(19) United States
(12) Patent Application Publication
(10) Pub. No.: US 2007/0278589 A1
(43) Pub. Date: Dec. 6, 2007

(54) Semiconductor device and fabrication method thereof

(76) Inventors: Nobuyuki Tamura, Kyoto (JP); Jun Suzuki, Kyoto (JP)

Correspondence Address: MCDERMOTT WILL & EMERY LLP, 600 13TH STREET, NW, WASHINGTON, DC, 20005-3096, US

(21) Appl. No.: 11/654,672

(22) Filed: Jan. 18, 2007

(30) Foreign Application Priority Data
Jun. 1, 2006 (JP) 2006-153372

(51) Int. Cl. H01L 31/00

(52) U.S. Cl. 257/371; 257/E31.001

(57) ABSTRACT

A semiconductor device includes: an NMIS transistor on an NMIS region of a semiconductor substrate; a PMIS transistor on a PMIS region of the semiconductor substrate; and a stress dielectric film continuously provided on the semiconductor substrate to cover the NMIS transistor and PMIS transistor, the stress dielectric film having internal stress, wherein part of the stress dielectric film extending over the NMIS region has tensile internal stress compared to part of the stress dielectric film extending over the PMIS region.

### BACKGROUND OF THE INVENTION

1. Field of the Invention

The present invention relates to a semiconductor device including a stress dielectric film provided on a semiconductor substrate to cover NMIS and PMIS transistors, the stress dielectric film having internal stress, wherein part of the stress dielectric film extending over an NMIS region has greater tensile stress compared to part of the stress dielectric film extending over a PMIS region. The present invention further relates to a fabrication method of the above-mentioned semiconductor device.

2. Description of the Prior Art

In recent years, structures and methods have been proposed in which for the purpose of improving current drivability of a semiconductor device, a dielectric film having internal stress and covering NMIS and PMIS transistors is used to improve electron mobility. In an example of such proposed methods, a nitride film having tensile internal stress is formed on the whole area of a semiconductor substrate by LPCVD to cover NMIS and PMIS transistors; part of the nitride film extending over the PMIS transistor is removed; and then, a nitride film having compressive stress is formed on the whole area of the semiconductor substrate 1 by PECVD, which realizes a structure in which the nitride film having the compressive stress is provided on a PMIS region and the nitride film having the tensile internal stress is provided on a PMIS region.

FIGS. 6A through 6E are cross sections illustrating a conventional fabrication method of a semiconductor device in the order of steps.

In a structure shown in FIG. 6A, a semiconductor substrate 101 includes an NMIS region 103 having a p-type well and a PMIS region 104 having an n-type well, the NMIS region 103 and the PMIS region 104 being separated from each other by a device isolation 102. A gate section of an NMIS transistor is provided on the NMIS region 103, the gate section including a gate dielectric film 107 and a gate electrode 109. A gate section of a PMIS transistor is provided on the PMIS region 104, the gate section including a gate dielectric film 108 and a gate electrode 110. The NMIS region 103 includes n-type source/drain regions 119 in which an n-type dopant ion is implanted. The n-type source/drain regions 119 have n-type extension regions 114 provided in portions beneath both side surfaces of the gate section of the NMIS transistor. Likewise, the PMIS region 104 includes p-type source/drain regions 102 having p-type extension regions 115 in which a p-type dopant ion is implanted. Further, side walls 117 and 118 are respectively provided on the side surfaces of the gate sections of the NMIS and PMIS transistors. Moreover, silicide layers 121 are provided on the gate electrodes 109 and 110 and on the source/drain regions 119 and 120.

In addition to the structure shown in FIG. 6A, in FIG. 6B, a nitride film 122a having tensile internal stress is formed on the whole surface of the semiconductor substrate 101 by CVD to cover the NMIS and PMIS transistors. Then, a first resist mask 128 having an opening over the PMIS region 104 is formed on the nitride film 122a.

Next, referring to FIG. 6C, part of the nitride film 122a extending over the PMIS region 104 in the structure shown in FIG. 6B is etched and removed by using the first resist mask 128. Then, the first resist mask 128 is removed.

Subsequently, referring to FIG. 6D, a nitride film 122b having compressive stress is formed on the whole surface of the semiconductor substrate 101 by CVD. Then, a second resist mask 130 having an opening over the NMIS region 103 is formed on the nitride film 122b.

Next, referring to FIG. 6E, the second resist mask 130 is used to etch and remove part of the nitride film 122b extending over the nitride film 122a. Then, the second resist mask 130 is removed. After that, for example, a wiring section is formed (see, for example, Japanese Laid-Open Patent Publication No. 2003-60076).

However, the conventional fabrication method of the semiconductor device described above has a great risk of damaging the source/drain regions 120, the gate electrode 121, the silicide layers 121, or the side walls 118 by removing the nitride film 122a having the tensile internal stress on the PMIS region 104 in the step illustrated with FIG. 6C, which deteriorates the characteristics of the PMIS transistor.

### SUMMARY OF THE INVENTION

In view of the above-mentioned problem, an object of the present is to provide a semiconductor device fabrication method for providing greater tensile internal stress to part of a dielectric film extending over an NMIS region compared to part of the dielectric film extending over a PMIS region without damaging MIS transistors, the dielectric film having internal stress. Another object of the present invention is to provide a semiconductor device fabricated according to the above-mentioned method.

A semiconductor device according to one aspect of the present invention includes: an NMIS transistor on an NMIS region of a semiconductor substrate; a PMIS transistor on a PMIS region of the semiconductor substrate; and a stress dielectric film continuously provided on the semiconductor substrate to cover the NMIS transistor and PMIS transistor, the stress dielectric film having internal stress, wherein part of the stress dielectric film extending over the NMIS region has greater tensile internal stress compared to part of the stress dielectric film extending over the PMIS region.

In the semiconductor device according to one aspect of the present invention, the part of the stress dielectric film extending over the NMIS region has the greater tensile internal stress compared to the part of the stress dielectric film extending over the PMIS region, which improves drivability of the NMIS transistor. Moreover, the stress dielectric film is continuously formed, and the part of the stress dielectric film extending over the NMIS region has the greater tensile internal stress compared to the part of the stress dielectric film extending over the PMIS region, which makes it possible to realize an NMIS transistor having excellent drivability without damaging the NMIS and PMIS transistors in a fabrication process.

In the semiconductor device according to one aspect of the present invention, it is preferable that the part of the stress dielectric film extending over the PMIS region has compressive internal stress.

In this structure, it is possible to improve not only the drivability of the NMIS transistor, but also drivability of the PMIS transistor.

In the semiconductor device according to one aspect of the present invention, the part of the stress dielectric film extending over the NMIS region may have a hydrogen content lower than that of the part of the stress dielectric film extending over the PMIS region. In this case, the part of the stress dielectric film extending over the NMIS region has the greater tensile internal stress compared to the part of the stress dielectric film extending over the PMIS region.

In the semiconductor device according to one aspect of the present invention, it is preferable that the NMIS transistor includes a first gate section including a first gate dielectric film and a first gate electrode on the NMIS region, a first side wall dielectric film on a side surface of the first gate section, and a first extension diffusion region in a portion of the NMIS region situated laterally to the first gate section; and the PMIS transistor includes a second gate section including a second gate dielectric film and a second gate electrode on the PMIS region, a second side wall dielectric film on a side surface of the second gate section, and a second extension diffusion region in a portion of the PMIS region situated laterally to the second gate section.

The semiconductor device according to one aspect of the present invention may further include an interlayer dielectric film on the stress dielectric film, wherein the part of the interlayer dielectric film extending over the NMIS region has tensile internal stress, and the part of the interlayer dielectric film extending over the PMIS region has compressive internal stress. In this structure, the drivability of the NMIS and PMIS transistors is further improved.

A semiconductor device fabrication method according to one aspect of the present invention includes the steps of: (a) forming an NMIS transistor on an NMIS region of a semiconductor substrate, and forming a PMIS transistor on a PMIS region of the semiconductor substrate; (b) forming a stress dielectric film having internal stress on the semiconductor substrate to cover the NMIS transistor and the PMIS transistor; (c) forming a protection film impermeable to ultraviolet light on the stress dielectric film to mask the PMIS region; and (d) after step (c), irradiating the semiconductor substrate with ultraviolet light to provide greater tensile internal stress to part of the stress dielectric film extending over the NMIS region compared to part of the stress dielectric film extending over the PMIS region.

In the semiconductor device fabrication method according to one aspect of the present invention, the protection film formed on the PMIS region is used as a mask for irradiation with the ultraviolet light in order to provide the greater tensile internal stress to the part of the stress dielectric film extending over the NMIS region compared to the part of the stress dielectric film extending over the PMIS region. Therefore, it is possible to improve drivability of the NMIS transistor. Moreover, in the fabrication method, the ultraviolet light is used to provide the greater tensile internal stress to the part of the stress dielectric film extending over the NMIS region compared to the part of the stress dielectric film extending over the PMIS region. Therefore, it is possible to realize an NMIS transistor having excellent drivability without damaging the NMIS and the PMIS transistor.

In the semiconductor device fabrication method according to one aspect of the present invention, it is preferable that step (b) further includes forming the stress dielectric film having compressive internal stress.

In this method, it is possible to improve not only the drivability of the NMIS transistor, but also drivability of the PMIS transistor.

In the semiconductor device according to one aspect of the present invention, irradiation with the ultraviolet light in step (d) reduces a hydrogen content in the part of the stress dielectric film extending over the NMIS region compared to that in the part of the stress dielectric film extending over the PMIS region. In this case, the part of the stress dielectric film extending over the NMIS region has the greater tensile internal stress compared to the part of the stress dielectric film extending over the PMIS region.

It is preferable that the semiconductor device fabrication method according to one aspect of the present invention further includes the step of forming an etching stopper film on the stress dielectric film after step (b) and before step (c).

Forming the protection film masking the PMIS region causes a reduction of film in the stress dielectric film on the NMIS region. However, in this method, it is possible to prevent the reduction of film. Therefore, a reduction in tensile internal stress, which would be caused by the reduction of film, is suppressed in the part of the stress dielectric film extending over the NMIS region, and thus the part of the stress dielectric film extending over the NMIS region has excellent tensile internal stress.

It is preferable that the semiconductor device fabrication method according to one aspect of the present invention further includes the step of (e) forming an interlayer dielectric film on the stress dielectric film after step (b) and before step (c), wherein step (c) further includes forming the protection film on the interlayer dielectric film to mask the PMIS region.

Forming the protection film masking the PMIS region causes a reduction of film in the stress dielectric film on the NMIS region. However, in this method, it is possible to prevent the reduction of film. Therefore, a reduction in tensile internal stress, which would be caused by the reduction of film, is suppressed in the part of the stress dielectric film extending over the NMIS region, and thus the part of the stress dielectric film extending over the NMIS region has excellent tensile internal stress.

In the semiconductor device fabrication method according to one aspect of the present invention, step (e) is the step of forming a first interlayer dielectric film having compressive internal stress on the part of the stress dielectric film extending over the PMIS region, step (c) includes forming the protection film on the first interlayer dielectric film to mask the PMIS region, and the fabrication method may further include the step of forming a second interlayer dielectric film having tensile internal stress on the part of the stress dielectric film extending over the NMIS region after step (d). In this method, it is possible to further improve the drivability of the NMIS and PMIS transistors.

It is preferable that in the semiconductor device fabrication method according to one aspect of the present invention, a surface of a liner film is planarized before step (c) on which the protection film is to be formed.

In the semiconductor device fabrication method according to one aspect of the present invention, a film containing silicon may be used as the protection film.

In the semiconductor device fabrication method according to one aspect of the present invention, it is preferable that the protection film has a film thickness equal to or greater than 5 nm. In this method, it is possible to prevent the transmission of ultraviolet light.

In the semiconductor device fabrication method according to one aspect of the present invention, the protection film may be formed on the interlayer dielectric film, and in this case, a film containing nitride may be used as the protection film.

In the semiconductor device fabrication method according to one aspect of the present invention, it is preferable that in step (d), the substrate has a temperature equal to or higher than 350° C. and equal to or lower than 600° C. In this method, it is possible to provide tensile internal stress to the part of the stress dielectric film on the NMIS region, and it is possible to prevent thermal damage on the NMIS and PMIS transistors.

In the semiconductor device fabrication method according to one aspect of the present invention, it is preferable that in step (a), the NMIS transistor includes a first gate section including a first gate dielectric film and a first gate electrode on the NMIS region, a first side wall dielectric film on a side surface of the first gate section, and a first extension diffusion region in a portion of the NMIS region situated laterally to the first gate section; and the PMIS transistor includes a second gate section including a second gate dielectric film and a second gate electrode on the PMIS region, a second side wall dielectric film on a side surface of the second gate section, and a second extension diffusion region in a portion of the PMIS region situated laterally to the second gate section.

As described above, in a semiconductor device and a fabrication method thereof according to one aspect of the present invention, the protection film formed on the PMIS region is used as a mask for irradiation with the ultraviolet light in order to provide the greater tensile internal stress to part of the stress dielectric film extending over the NMIS region compared to part of the stress dielectric film extending over the PMIS region. Therefore, it is possible to improve drivability of the NMIS transistor without damaging the NMIS and PMIS transistors.

### BRIEF DESCRIPTION OF THE DRAWINGS

FIG. 1 is a cross section illustrating a structure of a semiconductor device according to Embodiment 1 of the present invention.

FIGS. 2A through 2E are cross sections illustrating a semiconductor device fabrication method according to Embodiment 1 of the present invention in the order of steps.

FIGS. 3A through 3E are cross sections illustrating the semiconductor device fabrication method according to Embodiment 1 of the present invention in the order of steps.

FIGS. 4A through 4C are cross sections illustrating a semiconductor device fabrication method according to Embodiment 2 of the present invention in the order of steps.

FIGS. 5A through 5C are cross sections illustrating a semiconductor device fabrication method according to Embodiment 3 of the present invention in the order of steps.

FIGS. 6A through 6E are cross sections illustrating a conventional fabrication method of a semiconductor device in the order of steps.

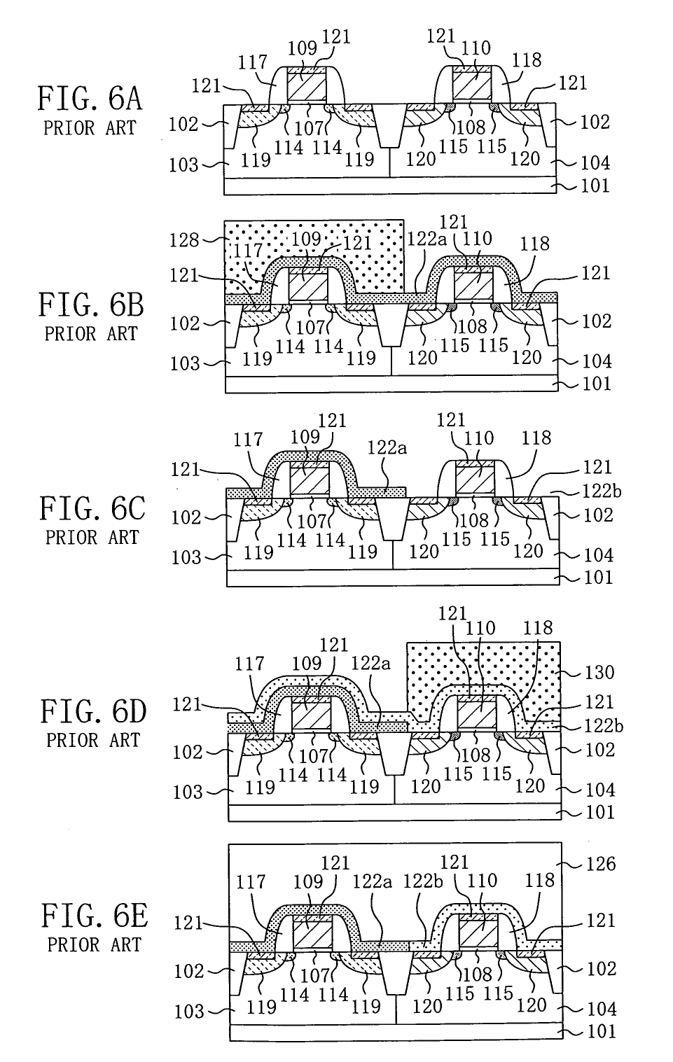

### DESCRIPTION OF THE PREFERRED EMBODIMENTS

### Embodiment 1

First, a semiconductor device according to Embodiment 1 of the present invention will be described.

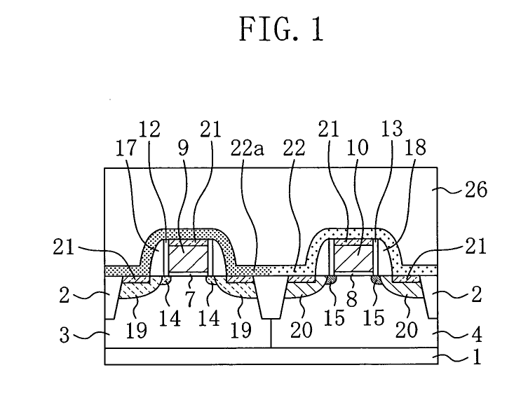

FIG. 1 shows a cross-sectional structure of the semiconductor device according to Embodiment 1 of the present invention.

As shown in FIG. 1, a semiconductor substrate 1 formed of, for example, silicon includes an NMIS region 3 having a p-type well and a PMIS region 4 having an n-type well, the NMIS region 3 and the PMIS region 4 being separated from each other by a device isolation 2.

A gate section of an NMIS transistor is provided on the NMIS region 3, the gate section including a gate dielectric film 7 and a gate electrode 9 formed in this order. A gate section of a PMIS transistor is provided on the PMIS region 4, the gate section including a gate dielectric film 8 and a gate electrode 10 formed in this order.

The NMIS region 3 includes n-type source/drain regions 19. The n-type source/drain regions 19 are impurity diffusion layers in which an n-type dopant ion, such as arsenic, is implanted. The n-type source/drain regions 19 have n-type extension regions 14. The junction depth of the n-type extension regions 14 is relatively shallow. The n-type extension regions 14 are provided in portions beneath both side surfaces of the gate section of the NMIS transistor. Likewise, the PMIS region 4 includes p-type source/drain regions 20 having p-type extension regions 15 in which a p-type dopant ion, such as boron, is implanted.

Offset spacers 12 formed by oxide films and having I-shape (plate shape) cross sections are provided on the side surfaces of the gate section of the NMIS transistor. Side walls 17 formed of, for example, silicon nitride (SiN) are provided on side surfaces of the offset spacers 12. Likewise, offset spacers 13 formed by oxide films and having I-shape cross sections are provided on side surfaces of the gate section of the PMIS transistor. Side walls 18 formed of, for example, silicon nitride are provided on side surfaces of the offset spacers 13. Moreover, on the gate electrodes 9 and 10 and on the source/drain regions 19 and 20, silicide layers 21 are provided. The silicide layers 21 are produced by a heat treatment causing a reaction of a metal film of Ni, Co, Ti, or the like with silicon.

A nitride film is continuously provided on the whole surface of the semiconductor substrate 1 to cover the NMIS transistor and the PMIS transistor. The nitride film is constituted of a nitride film 22a on the NMIS region 3 and a nitride film 22 on the PMIS region 4, where the nitride film 22a has tensile internal stress, and the nitride film 22 has compressive stress. Therefore, part of the nitride film 22a on the NMIS region 3 has greater tensile internal stress compared with part of the nitride film 22 on the PMIS region 4. An interlayer dielectric film 26 is provided on the nitride film 22 and the nitride film 22a. For example, a wiring section (not shown) is provided on the interlayer dielectric film 26.

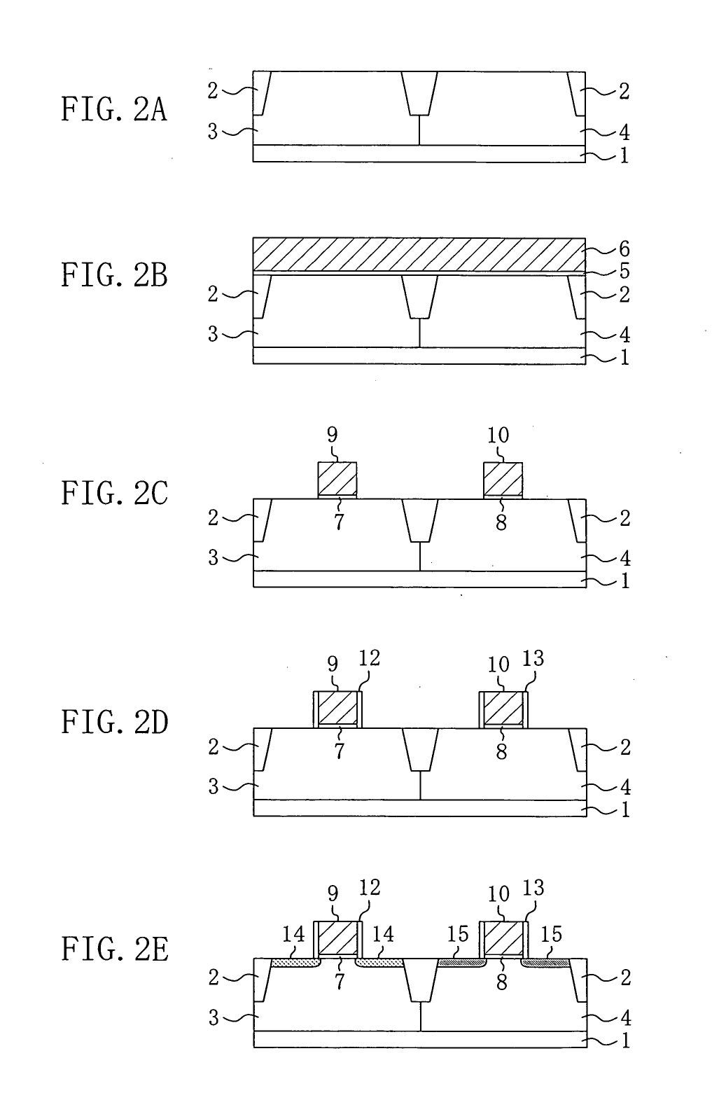

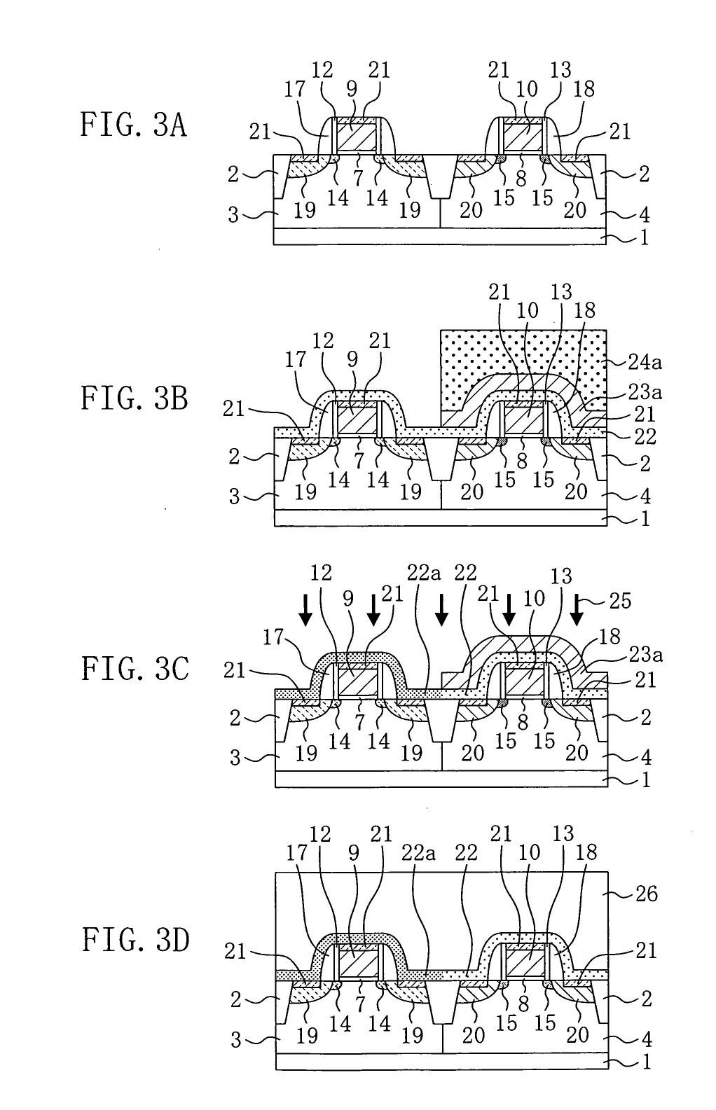

A semiconductor device fabrication method according to Embodiment 1 of the present invention will be described below with reference to FIGS. 2A through 2E and FIGS. 3A through 3D.

FIGS. 2A through 2E and FIGS. 3A through 3D are cross sections illustrating the semiconductor device fabrication method according to Embodiment 1 of the present invention in the order of steps.

First, referring to FIG. 2A, on the semiconductor substrate 1, a device isolation 2 is formed by using a general device isolation forming method. Then, a substrate 1 is doped to form an NMIS region 3 which has a p-type well and a PMIS region 4 which has an n-type well.

Next, referring to FIG. 2B, on the semiconductor substrate 1, a dielectric film 5 is formed by, for example, thermal oxidation, the dielectric film 5 containing, for example, SiO₂, SiON, or HfSiON. On the dielectric film 5, for example, a polysilicon film 6 having a thickness of about 140 nm is deposited.

Next, referring to FIG. 2C, photolithography and dry etching techniques are employed to pattern a gate section of an NMIS transistor in the NMIS region 3 and a gate section of a PMIS transistor in the PMIS region 4. The gate section of the NMIS transistor includes a gate dielectric film 7 and a gate electrode 9. The gate section of the PMIS transistor includes a gate dielectric film 8 and a gate electrode 10.

Next, referring to FIG. 2D, on the whole surface of the semiconductor substrate 1, an oxide film (not shown) having a thickness of about 14 nm is formed by chemical vapor deposition (CVD) to cover side surfaces and an upper surface of each gate section of the NMIS transistor and PMIS transistor. Then, an etch back process is performed to form offset side walls 12 and 13 having I-shape (plate shape) cross sections on the side surfaces of each gate section of the NMIS transistor and PMIS transistor. Note that, as the oxide film, for example, a high-temperature oxide (HTO) film may be used.

Next, referring to FIG. 2E, using the gate electrode 9 and the offset spacers 12 as a mask, an n-type dopant, such as arsenic, is implanted to form n-type extension regions 14 in the NMIS region 3 beneath both side surfaces of the gate section of the NMIS transistor. Moreover, using the gate electrode 10 and the offset spacers 13 as a mask, a p-type dopant, such as boron, is implanted to form p-type extension regions 15 in the PMIS region 4 beneath both side surfaces of the gate section of the PMIS transistor.

Next, referring to FIG. 3A, a silicon nitride film having a thickness of about 65 nm is deposited on the whole surface of the semiconductor substrate 1. Then, the silicon nitride film is etched back so as to form side walls 17 and 18 formed by, for example, the silicon nitride film respectively on side surfaces of the offset spacers 12 and 13. Subsequently, the gate electrode 9, the offset spacers 12, and the side walls 17 are used as an implantation mask to selectively implant the n-type dopant in the NMIS region 3 in order to form n-type source/drain regions 19. Moreover, the gate electrode 10, the offset spacers 13, and the side walls 18 is used as an implantation mask to selectively implant the p-type dopant in the PMIS region 4 in order to form p-type source/drain regions 20. Further, an activation process is performed by a thermal treatment for a short time at a temperature of about 1000° C. Then, a metal film of Ni, Co, Ti or the like is grown on the whole surface of the semiconductor substrate 1 by using a sputtering method, and then a thermal treatment is performed, so that a reaction of the metal film with silicon produces silicide layers 21 on the gate electrodes 9 and 10 and on the source/drain regions 19 and 20.

Next, referring to FIG. 3B, on the whole surface of the semiconductor substrate 1, a nitride film 22 having a thickness of about 30 nm and having compressive stress is formed by LPCVD to cover the NMIS transistor and the PMIS transistor. (Note that, the nitride film 22 may be a single layer or may be constituted of multiple layers.) Note that, in this case, a nitride film formed by an ordinary CVD method may be used as the nitride film 22. Subsequently, on the whole surface of the semiconductor substrate 1, a protection film 23a including a material impermeable to ultraviolet light (for example, a protection film 23a of amorphous silicon or polycrystalline silicon) is formed, the protection film 23a having a thickness of about 100 nm. Then, an etching process is performed by using a first resist mask 24a which has an opening over the NMIS region 3 so as to remove part of the protection film 23a extending over the NMIS region 3. A film thickness equal to or greater than 5 nm is required for the protection film 23a to prevent the transmission of ultraviolet light. However, for facilitating a patterning process, it is more preferable that the film thickness is 200 nm or less.

In this step, for example, an oxide film having a thickness of about 10 nm and being permeable to ultraviolet light may be formed as an etching stopper film on the nitride film 22, and then the protection film 23a may be formed. In this case, the oxide film serves as the etching stopper film at the time of removing the part of the protection film 23a extending over the NMIS region 3, so that it is possible to prevent a reduction of film in part of the nitride film 22 extending over the NMIS region 3.

Next, referring to FIG. 3C, the first resist mask 24a is removed. Then, the semiconductor substrate 1 is heated to a temperature of about 400° C., and irradiation with ultraviolet light 25 is performed on the whole surface of the semiconductor substrate 1. At this time, the ultraviolet light reaches the part of the nitride film 22 extending over the NMIS region 3, while part of the nitride film 22 extending over the PMIS region 4 is masked with the protection film 23a. As a result, the part of the nitride film 22 extending over the NMIS region 3 is transformed into a nitride film 22a having tensile internal stress. Consequently, part of the nitride film 22a extending over the NMIS region 3 has tensile internal stress, and the part of the nitride film 22 extending over the PMIS region 4 has the compressive stress. In other words, the ultraviolet light reduces the hydrogen content in the part of the nitride film 22 extending over the NMIS region 3, so that the part of the nitride film 22 extending over the NMIS region 3 is transformed into the nitride film 22a. Therefore, the hydrogen content in the part of the nitride film 22a extending over the NMIS region 3 is less than the hydrogen content in the part of the nitride film 22 extending over the PMIS region 4.

At the time of irradiation with the ultraviolet light 25, the semiconductor substrate 1 has a temperature of at least 350° C. at which tensile stress can be provided to the nitride film extending over the NMIS region 3. Considering thermal damage on the source/drain regions 19 and other members, it is more preferable that the temperature is 600° C. or less.

Next, referring to FIG. 3D, the protection film 23a remaining on the PMIS region 4 is removed. Then, the interlayer dielectric film 26 is formed on the nitride film 22 and the nitride film 22a. Subsequently, a contact, a wiring section, and the like will be formed.

In the semiconductor device fabrication method according to Embodiment 1 of the present invention, the nitride film 22 having the compressive stress is formed on the whole surface of the semiconductor substrate 1 to cover the PMIS transistor and the NMIS transistor; the protection film 23a impermeable to the ultraviolet light is formed to cover the PMIS region 4; and then, irradiation with the ultraviolet light is performed on the whole surface of the semiconductor substrate 1. In this method, it is possible to transform the part of the nitride film 22 extending over the NMIS region 3 into the nitride film 22a having the tensile internal stress. Therefore, the part of the nitride film 22a extending over the NMIS region 3 can be provided with greater tensile internal stress compared to the part of the nitride film 22 extending over the PMIS region 4 without damaging the source/drain regions 19 and 20, the gate electrodes 9 and 10, the silicide layers 21, and the side walls 17 and 18. This makes it possible to improve the drivability of the NMIS transistor. Moreover, in the semiconductor device formed in this method, irradiation with the ultraviolet light provides tensile internal stress to the part of the nitride film 22a extending over the NMIS region 3. Therefore, the part of the nitride film 22a extending over the NMIS region 3 and the part of the nitride film 22 extending over the PMIS region 4 are not separate, but continuously formed.

### Embodiment 2

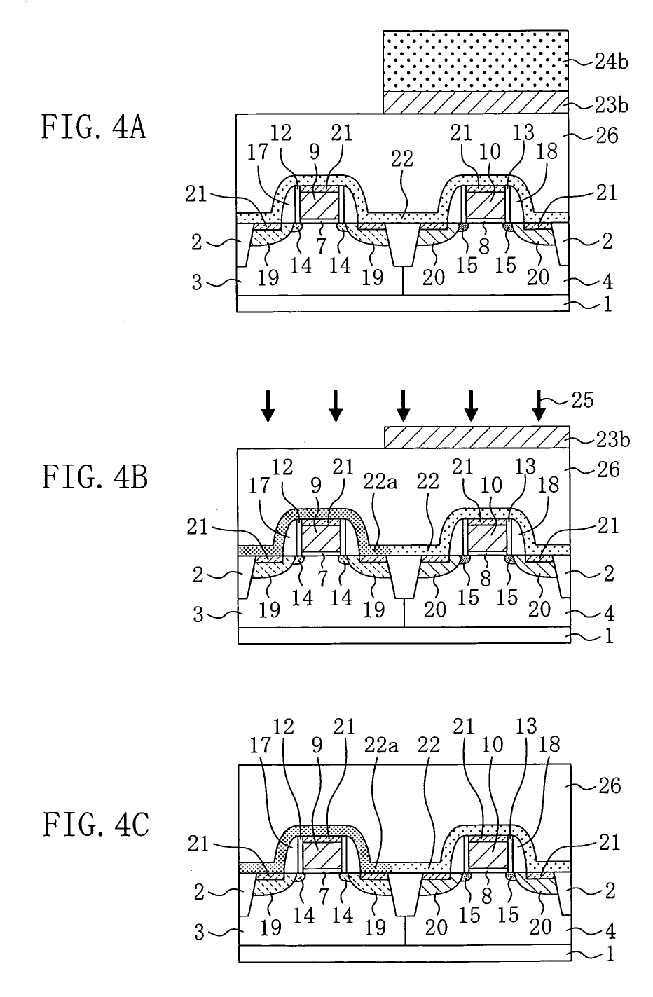

A semiconductor device fabrication method according to Embodiment 2 of the present invention will be described below with reference to FIGS. 2A through 2E and FIG. 3A, which have been referred to describe Embodiment 1, and FIGS. 4A through 4C. FIGS. 4A through 4C are cross sections illustrating the fabrication method according to Embodiment 2 of the present invention in the order of steps.

First, the steps described with reference to FIGS. 2A through 2E and FIG. 3A of Embodiment 1 are performed in the same manner. These steps are as described in Embodiment 1.

Next, referring to FIG. 4A, on the whole surface of the semiconductor substrate 1, a nitride film 22 having a thickness of about 30 nm and having compressive stress is formed by LPCVD to cover the NMIS transistor and the PMIS transistor. (Note that, the nitride film 22 may be a single layer or may be constituted of multiple layers.) Note that, in this case, a nitride film formed by an ordinary CVD method may be used as the nitride film 22. Subsequently, an interlayer dielectric film 26 is formed on the nitride film 22. Then, a surface of the interlayer dielectric film 26 is planarized by, for example, Chemical Mechanical Polishing (hereinafter referred to as CMP).

Subsequently, on the interlayer dielectric film 26, a protection film 23b including a material impermeable to ultraviolet light (in this case, for example, a protection film 23b of polycrystalline silicon or amorphous silicon) is formed, the protection film 23b having a thickness of about 100 nm. Then, an etching process is performed by using a first resist mask 24b which has an opening over the NMIS region 3 so as to remove part of the protection film 23b extending over the NMIS region 3. A film thickness equal to or greater than 5 nm is required for the protection film 23b to prevent the transmission of ultraviolet light. However, for facilitating a patterning process, it is more preferable that the film thickness is 200 nm or less.

In this case, it is preferable that the opening over the NMIS region 3 in the first resist mask 24b is small so that a protection film 23b to be formed by using such first resist mask 24b may not transmit ultraviolet light 25 to part of the nitride film 22 extending over the PMIS region 4 when irradiation with the ultraviolet light 25 on the semiconductor substrate 1 is performed in a later step. Therefore, the protection film 23b is formed such that the protection film 23b extends to the NMIS region 3 beyond the middle point of the element spacer region 2 between the NMIS region 3 and the PMIS region 4. In a case where a resist mask which has an opening over the NMIS region 3 used in a previous step is used as the first resist mask 24b without modification, the quantity of the ultraviolet light 25 described later is controlled so as to suppress the ultraviolet light 25 leaking to the part of the nitride film 22 extending over the PMIS region 4.

Next, referring to FIG. 4B, the first resist mask 24b is removed. Then, the semiconductor substrate 1 is heated to a temperature of about 400° C., and irradiation with the ultraviolet light 25 is performed on the whole surface of the semiconductor substrate 1. At this time, the ultraviolet light reaches part of the nitride film 22 extending over the NMIS region 3, while part of the nitride film 22 extending over the PMIS region 4 is masked with the protection film 23b. As a result, the part of the nitride film 22 extending over the NMIS region 3 is transformed into a nitride film 22a having tensile internal stress. Consequently, part of the nitride film 22a extending over the NMIS region 3 has tensile internal stress, and the part of the nitride film 22 extending over the PMIS region 4 has the compressive stress. In other words, the ultraviolet light reduces the hydrogen content in the part of the nitride film 22 extending over the NMIS region 3, so that the nitride film 22 extending over the NMIS region 3 is transformed into the nitride film 22a having the tensile internal stress. As a result, the hydrogen content in the part of the nitride film 22a extending over the NMIS region 3 is lower than the hydrogen content in the part of the nitride film 22 extending over the PMIS region 4. Therefore, the part of the nitride film 22a extending over the NMIS region 3 has greater tensile internal stress than the part of the nitride film 22 extending over the PMIS region 4.

At the time of irradiation with the ultraviolet light 25, the semiconductor substrate 1 has a temperature of at least 350° C. at which tensile stress can be provided to the nitride film extending over the NMIS region 3. Considering thermal damage on the source/drain regions 19 and other members, it is more preferable that the temperature is 600° C. or less.

Next, referring to FIG. 4C, the protection film 23b remaining on the PMIS region 4 is removed. Subsequently, a contact, a wiring section, and the like will be formed.

In the semiconductor device fabrication method according to Embodiment 2 of the present invention, the nitride film 22 having the compressive stress is formed on the whole surface of the semiconductor substrate 1 to cover the PMIS transistor and the NMIS transistor; in Embodiment 2, the interlayer dielectric film 26 is further formed and planarized; the protection film 23a impermeable to the ultraviolet light is formed on the interlayer dielectric film 26 to cover the PMIS region 4; and then, irradiation with the ultraviolet light is performed on the whole surface of the semiconductor substrate 1. In this method, it is possible to transform the part of the nitride film 22 extending over the NMIS region 3 into the nitride film 22a having the tensile internal stress. Therefore, the part of the nitride film 22a extending over the NMIS region 3 can be provided with greater tensile internal stress compared to the part of the nitride film 22 extending over the PMIS region 4 without damaging the source/drain regions 19 and 20, the gate electrodes 9 and 10, the silicide layers 21, and the side walls 17 and 18. This makes it possible to improve the drivability of the NMIS transistor. Moreover, in the time of etching the protection film 23b, the nitride film 22a is not etched, because the protection film 23b is provided on the interlayer dielectric film 26. Therefore, a reduction of film does not occur in the nitride film 22a. In this structure, it is possible to prevent a stress reduction which would be caused by the reduction of film.

The semiconductor device fabricated according to the fabrication method according to Embodiment 2 has the structure shown in FIG. 4C. The structure shown in FIG. 4C is not described in detail again because the structure in FIG. 4C is substantially the same as the structure shown in FIG. 1. Moreover, irradiation with the ultraviolet light provides tensile internal stress to the part of the nitride film 22a extending over the NMIS region 3. Therefore, the structure in the Embodiment 2 is also similar to the structure in Embodiment 1 in the part of that the nitride film 22a extending over the NMIS region 3 and the part of the nitride film 22 extending over the PMIS region 4 are not separate, but continuously formed. This feature is different from the conventional method.

### Embodiment 3

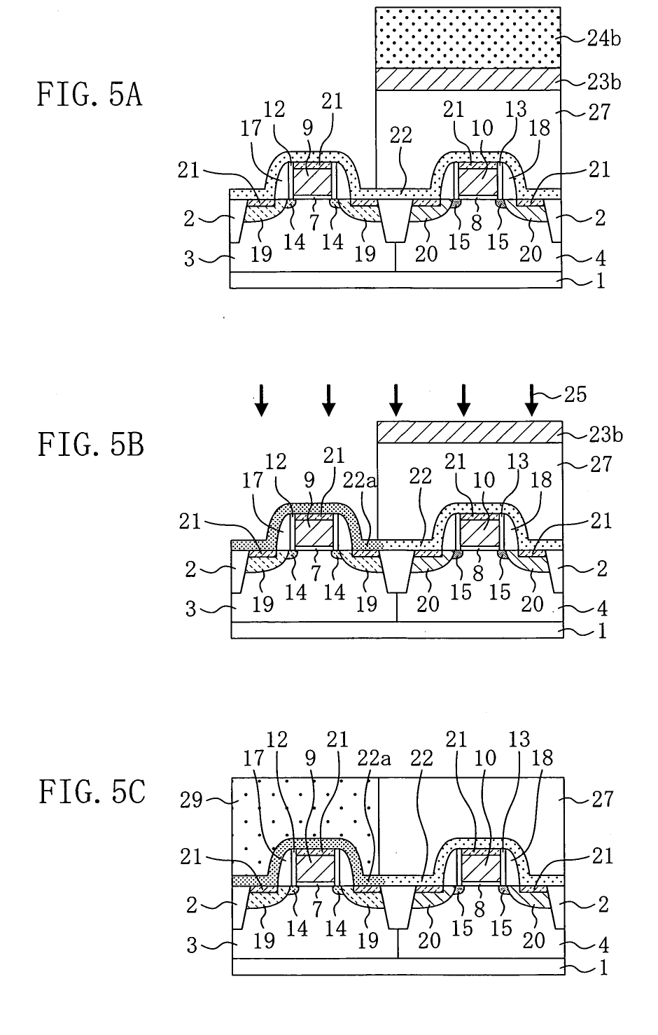

A semiconductor device fabrication method according to Embodiment 3 of the present invention will be described below with reference to FIGS. 2A through 2E and FIG. 3A, which have been referred to describe Embodiment 1, and FIGS. 5A through 5C. FIGS. 5A through 5C are cross sections illustrating the fabrication method according to Embodiment 3 of the present invention in the order of steps.

First, the steps described with reference to FIGS. 2A through 2E and FIG. 3A of Embodiment 1 are performed in the same manner. These steps are as described in Embodiment 1.

Next, referring to FIG. 5A, on the whole surface of the semiconductor substrate 1, a nitride film 22 having a thickness of about 30 nm and having compressive stress is formed by LPCVD to cover the NMIS transistor and the PMIS transistor. (Note that, the nitride film 22 may be a single layer or may be constituted of multiple layers.) Note that, in this case, a nitride film formed by an ordinary CVD method may be used as the nitride film 22. Subsequently, an interlayer dielectric film 27, such as an HDP (High-Density-Plasma)-NSG (Nondoped-Silicate-Glass) film, having compressive stress, is formed on the nitride film 22. Then, a surface of the interlayer dielectric film 27 is planarized by, for example, CMP.

Subsequently, on the interlayer dielectric film 27, a protection film 23b including a material impermeable to ultraviolet light (in this case, for example, a protection film 23b of amorphous silicon) is formed, the protection film 23b having a thickness of about 100 nm. Then, an etching process is performed by using a first resist mask 24b which has an opening over the NMIS region 3 so as to remove part of the protection film 23b and the interlayer dielectric film 27 extending over the NMIS region 3. A film thickness equal to or greater than 5 nm is required for the protection film 23b to prevent the transmission of ultraviolet light. However, for facilitating a patterning process, it is more preferable that the film thickness is 200 nm or less.

In this case, it is preferable that the opening over the NMIS region 3 in the first resist mask 24b is small so that a protection film 23b to be formed by using such first resist mask 24b may not transmit ultraviolet light 25 to part of the nitride film 22 extending over the PMIS region 4 when irradiation with the ultraviolet light 25 on the semiconductor substrate 1 is performed in a later step. In a case where a resist mask which has an opening over the NMIS region 3 used in the previous step is used as the first resist mask 24b without modification, the quantity of ultraviolet light 25 described later is controlled so as to suppress the ultraviolet light 25 leaking to the part of the nitride film 22 extending over the PMIS region 4.

Next, referring to FIG. 5B, the first resist mask 24b is removed. Then, the semiconductor substrate 1 is heated to a temperature of about 400° C., and irradiation with the ultraviolet light 25 is performed on the whole surface of the semiconductor substrate 1. At this time, the ultraviolet light reaches part of the nitride film 22 extending over the NMIS region 3, while part of the nitride film 22 extending over the PMIS region 4 is masked with the protection film 23b. As a result, the part of the nitride film 22 extending over the NMIS region 3 is transformed into a nitride film 22a having tensile internal stress. Consequently, part of the nitride film 22a extending over the NMIS region 3 has tensile internal stress, and the part of the nitride film 22 extending over the PMIS region 4 has the compressive stress. In other words, the ultraviolet light reduces the hydrogen content in the part of the nitride film 22 extending over the NMIS region 3, so that the part of the nitride film 22 extending over the NMIS region 3 is transformed into the nitride film 22a having the tensile internal stress. As a result, the hydrogen content in the part of the nitride film 22a extending over the NMIS region 3 is lower than the hydrogen content in the part of the nitride film 22 extending over the PMIS region 4. Therefore, the part of the nitride film 22a extending over the NMIS region 3 has greater tensile internal stress than the part of the nitride film 22 extending over the PMIS region 4.

At the time of irradiation with the ultraviolet light 25, the semiconductor substrate 1 has a temperature of at least 350° C. at which tensile stress can be provided to the nitride film extending over the NMIS region 3. Considering thermal damage on the source/drain regions 19 and other members, it is more preferable that the temperature is 600° C. or less.

Next, referring to FIG. 5C, an interlayer dielectric film 29, such as TEOS (Tetraethylrthosilicate) film, having tensile internal stress is formed on the whole surface of the semiconductor substrate 1. Then, CMP is performed to polish and remove the interlayer dielectric film 29 as far as the interlayer dielectric film 29 is planarized and the protection film 23b on the PMIS region 4 is removed. After that, a contact, a wiring section and the like are formed.

In the semiconductor device fabrication method according to Embodiment 3 of the present invention, the nitride film 22 having the compressive stress is formed on the whole surface of the semiconductor substrate 1 to cover the PMIS transistor and the NMIS transistor; the interlayer dielectric film 27 having compressive stress is selectively formed on the PMIS region 4; the protection film 23b impermeable to the ultraviolet light 25 is formed on the interlayer dielectric film 27 being planarized; and then, irradiation with the ultraviolet light is preformed on the whole surface of the semiconductor substrate 1. In this method, it is possible to transform the part of the nitride film 22 extending over the NMIS region 3 into the nitride film 22a having the tensile internal stress. Therefore, the part of the nitride film 22a extending over the NMIS region 3 can be provided with greater tensile internal stress compared to the part of the nitride film 22 extending over the PMIS region 4 without damaging the source/drain regions 19 and 20, the gate electrodes 9 and 10, the silicide layers 21, and the side walls 17 and 18. This makes it possible to improve the drivability of the NMIS transistor. After the formation of the nitride film 22a having the tensile internal stress, the interlayer dielectric film 29 having the tensile internal stress is further formed on the NMIS region 3. As a result, the nitride film 22a and the interlayer dielectric film 29 having the tensile internal stress are provided on the NMIS region 3 to cover the NMIS transistor. The nitride film 22 and the interlayer dielectric film 27 having the compressive internal stress are provided on the PMIS region 4 to cover the PMIS transistor. Therefore, it is possible to improve the drivability of the NMIS transistor and PMIS transistor.

The semiconductor device fabricated according to the fabrication method of Embodiment 3 has the structure shown in FIG. 5C. The structure in FIG. 5C is different from the structure shown in FIG. 1 in that the interlayer dielectric film of Embodiment 3 is constituted of the interlayer dielectric film 27 and the interlayer dielectric film 29, where the interlayer dielectric film 27 is formed on the PMIS region 4 and having the compressive internal stress, and the interlayer dielectric film 29 is formed on the NMIS region 3 and having the tensile internal stress. However, other components correspond to each other. Therefore, the explanation of the corresponding components is omitted. As described above, the above-mentioned difference in structure improves the drivability of the NMIS transistor and PMIS transistor more than the structure in FIG. 1 improves it. Moreover, irradiation with the ultraviolet light provides the tensile internal stress to the part of the nitride film 22a extending over the NMIS region 3. Therefore, the structure in the Embodiment 3 is also similar to the structure shown in FIG. 1 in that the part of the nitride film 22a extending over the NMIS region 3 and the part of the nitride film 22 extending over the PMIS region 4 are not separate, but continuously formed. This feature is different from the conventional method.

The fabrication methods of a semiconductor device according to Embodiments 1 to 3 above are described with reference to a semiconductor device having a structure in which the offset side walls 12 and the sidewalls 17 constituting a first sidewall dielectric films and the offset side walls 13 and the side walls 18 constituting a second side wall dielectric films are formed on the side surfaces of the gate electrodes 9 and 10. However, the present invention can be applied to a semiconductor device having a structure in which as the first and second side wall dielectric films, instead of or together with the offset side walls 12 and 13, dielectric films having L-shape cross sections are provided on the side surfaces of the side walls 17 and 18.

Moreover, in Embodiments 1 to 3, as a material for the protection film, other than the film including silicon, any material characterized by being impermeable to the ultraviolet light 25 may be selected and used in accordance with structures or fabrication steps of semiconductor devices. For example, in Embodiments 2 and 3, a protection film 23b formed by a nitride film may be used, because the protection film 23b is formed on the interlayer dielectric film 26 or 27.

The present invention is applicable to a semiconductor device and a semiconductor device fabrication method in which for a purpose of improving current drivability of a semiconductor device, a dielectric film having internal stress and covering NMIS and PMIS transistors is used to improve electron and hole mobility.

What is claimed is:

1. A semiconductor device comprising:
an NMIS transistor on an NMIS region of a semiconductor substrate;
a PMIS transistor on a PMIS region of the semiconductor substrate; and
a stress dielectric film continuously provided on the semiconductor substrate to cover the NMIS transistor and PMIS transistor, the stress dielectric film having internal stress,
wherein part of the stress dielectric film extending over the NMIS region has greater tensile internal stress compared to part of the stress dielectric film extending over the PMIS region.

2. A semiconductor device of claim 1, wherein the part of the stress dielectric film extending over the PMIS region has compressive internal stress.

3. A semiconductor device of claim 1, wherein the part of the stress dielectric film extending over the NMIS region has a hydrogen content lower than that of the part of the stress dielectric film extending over the PMIS region.

4. A semiconductor device of claim 1, wherein:
the NMIS transistor includes
a first gate section including a first gate dielectric film and a first gate electrode on the NMIS region,
a first side wall dielectric film on a side surface of the first gate section, and
a first extension diffusion region in a portion of the NMIS region situated laterally to the first gate section; and
the PMIS transistor includes
a second gate section including a second gate dielectric film and a second gate electrode on the PMIS region,
a second side wall dielectric film on a side surface of the second gate section, and
a second extension diffusion region in a portion of the PMIS region situated laterally to the second gate section.

5. A semiconductor device of claim 1, further comprising an interlayer dielectric film on the stress dielectric film, wherein
the part of the interlayer dielectric film extending over the NMIS region has tensile internal stress, and
the part of the interlayer dielectric film extending over the PMIS region has compressive internal stress.

6. A semiconductor device fabrication method, comprising the steps of:
(a) forming an NMIS transistor on an NMIS region of a semiconductor substrate, and forming a PMIS transistor on a PMIS region of the semiconductor substrate;
(b) forming a stress dielectric film having internal stress on the semiconductor substrate to cover the NMIS transistor and the PMIS transistor;
(c) forming a protection film impermeable to ultraviolet light on the stress dielectric film to mask the PMIS region; and
(d) after step (c), irradiating the semiconductor substrate with ultraviolet light to provide greater tensile internal stress to part of the stress dielectric film extending over the NMIS region compared to part of the stress dielectric film extending over the PMIS region.

7. A semiconductor device fabrication method of claim 6, wherein step (b) further includes forming the stress dielectric film having compressive internal stress.

8. A semiconductor device fabrication method of claim 6, wherein irradiation with the ultraviolet light in step (d) reduces a hydrogen content in the part of the stress dielectric film extending over the NMIS region compared to that in the part of the stress dielectric film extending over the PMIS region.

9. A semiconductor device fabrication method of claim 6, further comprising the step of forming an etching stopper film on the stress dielectric film after step (b) and before step (c).

10. A semiconductor device fabrication method of claim 6, further comprising the step of (e) forming an interlayer dielectric film on the stress dielectric film after step (b) and before step (c),
wherein step (c) further includes forming the protection film on the interlayer dielectric film to mask the PMIS region.

11. A semiconductor device fabrication method of claim 10, wherein
step (e) is the step of forming a first interlayer dielectric film having compressive internal stress on the part of the stress dielectric film extending over the PMIS region,
step (c) includes forming the protection film on the first interlayer dielectric film to mask the PMIS region, and
the semiconductor device fabrication method further includes the step of forming a second interlayer dielectric film having tensile internal stress on the part of the stress dielectric film extending over the NMIS region after step (d).

12. A semiconductor device fabrication method of claim 10, further comprising the step of planarizing a surface of a liner film before step (c) on which the protection film is to be formed.

13. A semiconductor device fabrication method of claim 6, wherein the protection film formed of silicon.

14. A semiconductor device fabrication method of claim 6, wherein the protection film has a film thickness equal to or greater than 5 nm.

15. A semiconductor device fabrication method of claim 10, wherein the protection film formed of nitride.

16. A semiconductor device fabrication method of claim 6, wherein in step (d), the substrate has a temperature equal to or higher than 350° C. and equal to or lower than 600° C.

17. A semiconductor device fabrication method of claim 6, wherein in step (a):
the NMIS transistor includes
a first gate section including a first gate dielectric film and a first gate electrode on the NMIS region,
a first side wall dielectric film on a side surface of the first gate section, and
a first extension diffusion region in a portion of the NMIS region situated laterally to the first gate section; and
the PMIS transistor includes
a second gate section including a second gate dielectric film and a second gate electrode on the PMIS region,
a second side wall dielectric film on a side surface of the second gate section, and
a second extension diffusion region in a portion of the PMIS region situated laterally to the second gate section.
